(19) United States
(12) Patent Application Publication
(10) Pub. No.: US 2010/0079205 A1
(43) Pub. Date: Apr. 1, 2010

(54) Multi-Channel Amplifier

(75) Inventor: Mikio KITANO, Hamamatsu-shi (JP)

Correspondence Address: CROWELL & MORING LLP;INTELLECTUAL PROPERTY GROUP, P.O. BOX 14300, WASHINGTON, DC, 20044-4300, US

(73) Assignee: Yamaha Corporation, Hamamatsu-shi (JP)

(21) Appl. No.: 12/566,161

(22) Filed: Sep. 24, 2009

(30) Foreign Application Priority Data
Sep. 30, 2008 (JP) 2008-253530

(51) Int. Cl. H03F 3/68

(52) U.S. Cl. 330/124 R

(57) ABSTRACT

Individual channels, to which a sound signal inputting portion In having a pin jack with NC setting and an amplifier circuit Amp are provided respectively, are provided in parallel from a higher order to a lower order every four L/R channels, and a cascade connection configuration in which a signal terminal S of the higher order channel is connected to an NC contact of the lower order channel successively is employed. Accordingly, the signal on the higher order side can be transmitted to the lower order side, and as a result there is no need to input the common (Bus) signal apart from the signals on the individual channels and also the changeover switch can be omitted.

### BACKGROUND OF THE INVENTION

The present invention relates to a multi-channel amplifier equipped with a plurality of channels having an inputting circuit and an amplifier circuit respectively.

A block diagram of a multi-channel amplifier (see “B3835 (8-Channel Amplifier) Owner's Manual”, 2002, Speaker Craft) in the related art is shown in FIG. 1. This multi-channel amplifier is employed mainly in a whole-building audio distributing system that is set up in a home in the United State.

In FIG. 1, this multi-channel amplifier has a pair of Bus channels and four pairs (eight) individual channels. The outputs of the individual channels are connected to the speakers that are set up in respective rooms such as a living room, a dining room, a bedroom, etc. Audio sources (e.g., a DVD player, an FM tuner, etc.) suitable for the rooms are connected to the inputs of these individual channels. The common audio signal fed to the individual channels to which the audio sources are not connected is input into the Bus channels. A changeover switch for switching the connection of an input terminal of that channel between an amplifier circuit Amp and the Bus channel is connected to the individual channels respectively.

In setting up the multi-channel amplifier, the person in charge connects each audio source to the appropriate channel, and also switches the changeover switches on the individual channels, to which the audio source is not connected, to the Bus channel side.

As described above, the conventional multi-channel amplifier always needs the input of the common Bus channel apart from the individual channels, and also needs the changeover switch that are set in setting up the amplifier every individual channel.

The manual switching operation for selecting whether the output signal of each individual channel should be connected to the individual input side or the common (Bus) input side is needed. Therefore, such manual switching operation is troublesome and it is feared that a setting error is made.

### SUMMARY OF THE INVENTION

It is an object of the present invention to provide multi-channel amplifier from which a common input terminal and a changeover switch are eliminated and whose setting at a time of setting up is facilitated.

The present invention provides the following arrangements.

(1) A multi-channel amplifier comprising:

first and second channels, each having an inputting connector to which an input plug is connectable and an amplifier circuit,

wherein the inputting connector of each of the first and second channel includes a signal terminal electrically connected to the amplifier circuit and a contact selectively and electrically connected to the signal terminal,

wherein the contact of the second channel is electrically connected to the signal terminal of the first channel,

wherein when the input plug is connected to the inputting connector of the second channel, the contact of the second channel is electrically separated from the signal terminal of the second channel and the input plug is electrically connected to the signal terminal of the second channel, and

wherein when the input plug is not connected to the inputting connector of the second channel, the contact of the second channel is electrically connected to the signal terminal of the second channel.

(2) The multi-channel amplifier according to (1), wherein the contact is a NC contact.
(3) The multi-channel amplifier according to (1), further comprising:

an external output terminal of the sound signal;

wherein the external output terminal is connected to the inputting connector of the second channel.

(4) The multi-channel amplifier according to (3), further comprising:

a buffer circuit of a high input impedance provided between the inputting connector of the second channel and the external output terminal.

(5) The multi-channel amplifier according to (1), further comprising:

a highest order channel having an outputting portion; and

signal selecting portions provided to the first and second channels, respectively, for selectively connecting one of the inputting connector of the corresponding first or second channel and the inputting connector of the highest order channel to the amplifier circuit of each channel.

(6) The multi-channel amplifier according to (5), further comprising:

a switching controlling portion which switches the signal selecting portions on the first and second channels collectively to a same side.

(7) A multi-channel amplifier comprising:

a first channel circuit having an inputting connector and an outputting portion; and

a plurality of second channels, each having an inputting connector to which an input plug is connectable and an amplifier circuit,

wherein the inputting connector of each of the second channels includes a signal terminal electrically connected to the amplifier circuit and a contact selectively and electrically connected to the signal terminal,

wherein the contact of each of the second channels is electrically connected to the outputting portion of the first channel,

wherein when the input plug is connected to the inputting connector of one of the second channels, the contact of the one of the second channels is electrically separated from the signal terminal of the one of the second channels and the input plug is electrically connected to the signal terminal of the one of the second channels, and

wherein when the input plug is not connected to the inputting connector of the one of the second channels, the contact of the one of the second channels is electrically connected to the signal terminal of the one of the second channels.

(8) The multi-channel amplifier according to (7), wherein the contact is a NC contact.
(9) A multi-channel amplifier comprising:

a first channel having an outputting portion;

a plurality of second channels, each having an inputting connector, an amplifier circuit and a signal selecting portion for selectively connecting one of the inputting connector of the first channel and the inputting connector thereof to the amplifier circuit thereof; and

a switching controlling portion which switches the signal selecting portions on the second channels collectively to a same side.

According to the present invention, when the sound signal is not input into the sound signal inputting portion of the concerned (second) channel (when the connector is not connected), the sound signal on the higher order (first) channel is input into the amplifier circuit of the concerned (second) channel. Therefore, the sound signal can be output from all channels not to switch manually the connection, while using the sound signal on the higher order side instead of the common signal.

### BRIEF DESCRIPTION OF THE DRAWINGS

FIG. 1 is a diagram showing a configuration of a multi-channel amplifier in the related art.

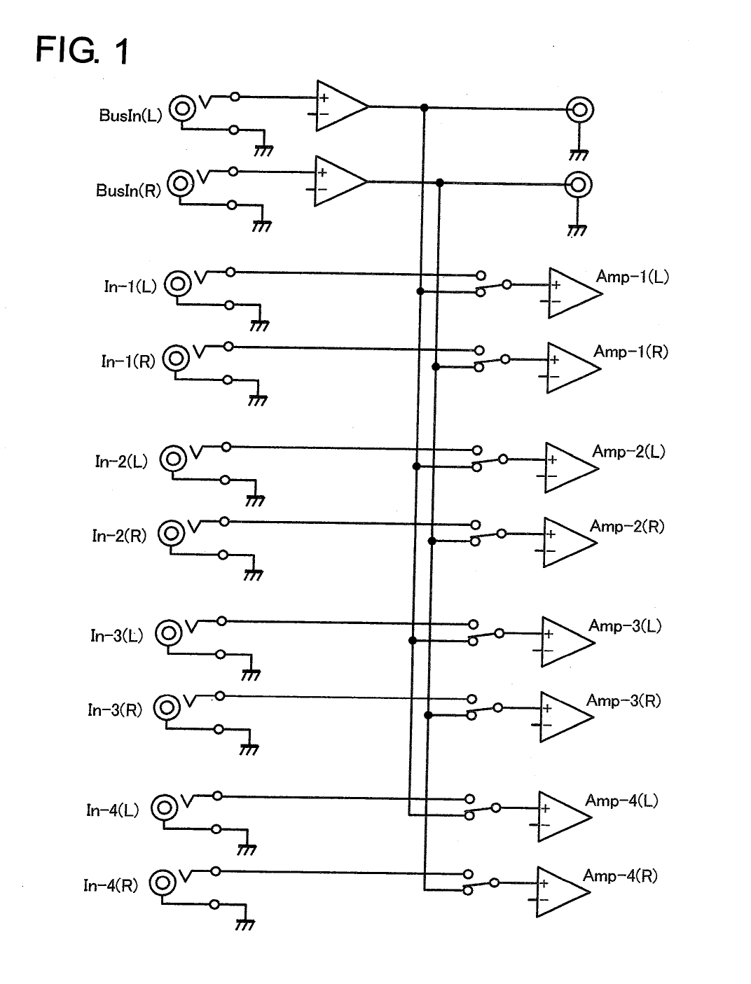

FIG. 2 is a diagram showing a configuration of a multi-channel amplifier according to a first embodiment of the present invention.

FIG. 3 is a diagram showing a configuration of a multi-channel amplifier according to a second embodiment of the present invention.

FIG. 4 is a diagram showing a configuration of a multi-channel amplifier according to a third embodiment of the present invention.

FIG. 5 is a diagram showing a configuration of a multi-channel amplifier according to a fourth embodiment of the present invention.

### DETAILED DESCRIPTION OF PREFERRED EMBODIMENTS

### First Embodiment

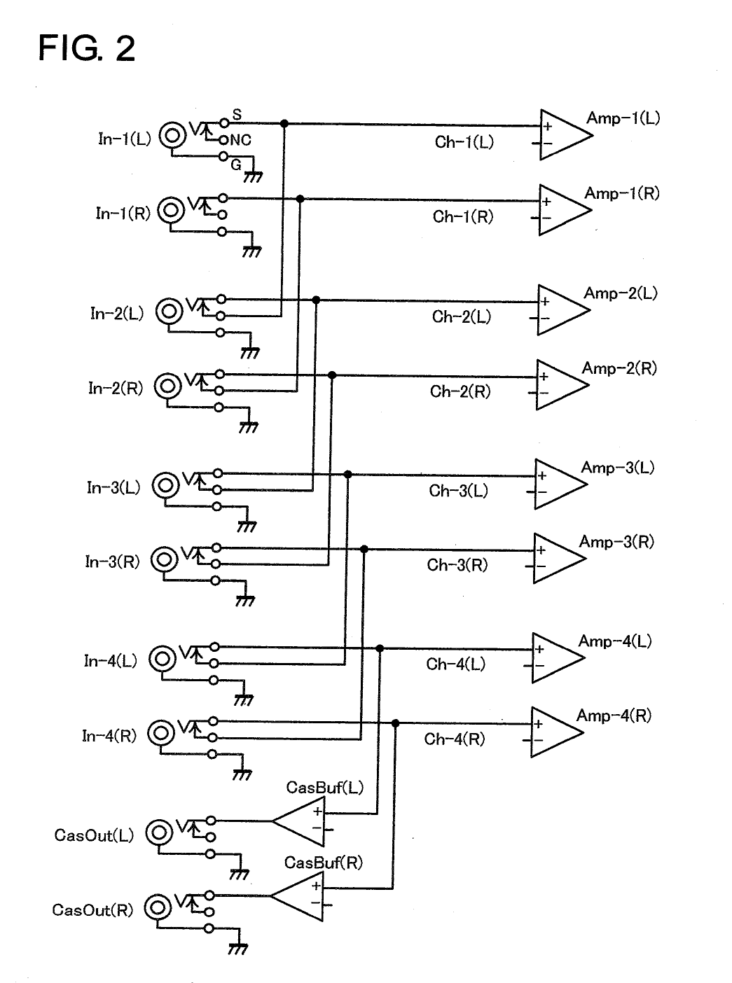

A multi-channel amplifier according to an embodiment of the present invention will be explained with reference to the drawings hereinafter. FIG. 2 is a block diagram of an input portion of a multi-channel amplifier according to a first embodiment of the present invention. This multi-channel amplifier has eight (four pairs of) individual channels. Each individual channel has a sound signal inputting portion In having a pin jack with NC (Normally Close) contact, and an amplifier circuit Amp for amplifying a signal in the audio frequency band. The pin jack with NC contact has a signal terminal S, a ground terminal G, and an NC contact. The NC contact means the contact that comes in touch with the signal terminal S when a plug through which an audio signal is provided is not inserted, but becomes separated from the signal terminal S when the plug is inserted. The signal terminal S is connected to the amplifier circuit Amp in each individual channel. Eight individual channels are combined in pairs respectively, and are constructed into four (first to fourth) pairs of stereo channels.

The left (L) channel system out of the first to fourth stereo channels will be explained hereunder. Here, the symbol (L) indicating the left channel will be omitted in the following explanation.

In the left channel system, four individual channels Ch-1 to Ch-4 are aligned in parallel from a higher order to a lower order. That is, the individual channel Ch-1 constitutes the highest order channel, and then the individual channel Ch-2, the individual channel Ch-3, and the individual channel Ch-4 are aligned toward a lower order. Then, the signal terminal S of the higher order channel is connected the amplifier circuit Amp on the same channel, and also is connected to the NC contact on the adjacent lower order channel. More particularly, the signal terminal S of the individual channel Ch-1 is connected to the NC contact on the lower order individual channel Ch-2, the signal terminal S of the individual channel Ch-2 is connected to the NC contact on the lower order individual channel Ch-3, and the signal terminal S of the individual channel Ch-3 is connected to the NC contact on the lower order individual channel Ch-4. The signal terminal S of the individual channel Ch-4 is connected to a cascade output terminal CasOut via a buffer CasBuf.

Here, the cascade output terminal CasOut is provided to output the audio signal to the lower order amplifier when the plural multi-channel amplifier are connected in parallel and are set up. The buffer CasBuf is a buffer amplifier that converts the audio signal into low impedance such that this multi-channel amplifier can drive an external device connected to the cascade output terminal CasOut. This buffer may be inserted between the signal terminal S of the higher order channel and the NC contact on the lower order channel.

With the above configuration, the common (Bus) input terminal and the individual selecting switches can be eliminated. Further, when the audio cable is inserted into a certain channel m, the signal on the channel m serves as the common input signal in a range between this channel m and the lower order channel just prior to the lower order channel n into which the audio cable is inserted. Thus, the sound signal inputting portions on a plurality of channels can be regarded and used flexibly as the common input terminal.

For example, when the audio cable is connected (the pin plug is inserted) only to the sound signal inputting portion (pin jack) In-1 on the individual channel 1, the sound signal being input into the sound signal inputting portion In-1 is input into not only an amplifier circuit Amp-1 on the individual channel Ch-1 but also amplifier circuits Amp-2 to Amp-4 on the individual channels Ch-2 to Ch-4. Also, this sound signal is output from the cascade output terminal CasOut. In this manner, when the audio cable is not connected to other channels, the sound signal inputting portion In-1 on the individual channel Ch-1 functions as the common input terminal.

When the audio cable is connected to the sound signal inputting portion In-3 on the individual channel 3 in a state that the audio cable is connected to the sound signal inputting portion In-1 on the individual channel 1, the sound signal of this audio cable is input from the signal terminal S of the pin jack to an amplifier circuit Amp-3 and also the NC contact of the pin jack on the individual channel Ch-3 is separated from the signal terminal S. Thus, the sound signal of the individual channel Ch-2 is not into the individual channel Ch-3. The sound signal being input into the individual channel Ch-3 is input into an amplifier circuit Amp-4 on the individual channel Ch-4 via the NC contact on the individual channel Ch-4 and also is output from the cascade output terminal CasOut. The sound signal on the individual channel Ch-1 is input into the individual channel Ch-2, like the above.

In this manner, in respective individual channels, the sound signal from the concerned audio cable is input when the audio cable is connected, while the sound signal from the higher order channel is input when the audio cable is not connected. Therefore, a labor of switching the switch in response to whether or not the audio cable is connected, or the like is not needed, and also a setting error can be eliminated.

With the above, the left channel system is explained. The right channel system is similarly constructed, and is operated totally similarly.

One of major applications of the multi-channel amplifier is the whole-building audio distributing system for home use, which is called a custom installation. The whole-building audio distributing system for home use is employed in such a mode that, for example, the multi-channel amplifier is put in a file cabinet in a living room and respective outputs of the individual channels are connected to the speakers provided to a living room, a dining room, a main bedroom, a pool, and the like.

### Second Embodiment

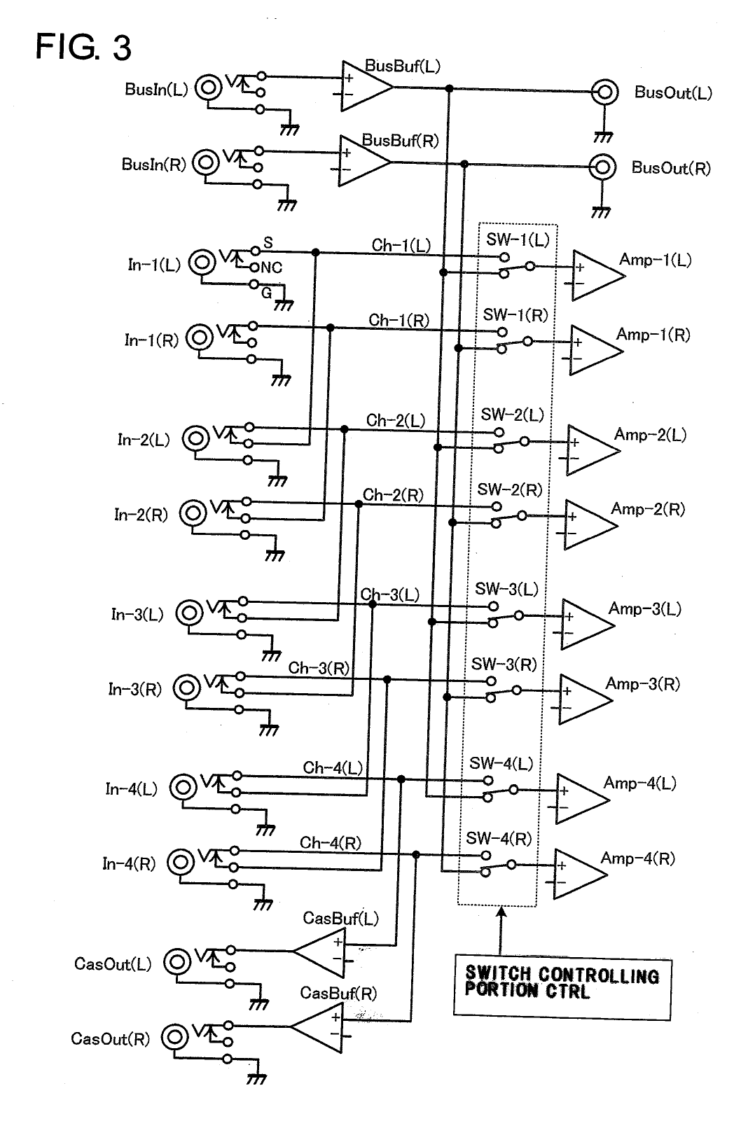

FIG. 3 is a block diagram of a multi-channel amplifier according to a second embodiment of the present invention. In this diagram, the same reference symbols are affixed to the same configurations as those in the first embodiment shown in FIG. 2, and their explanation will be omitted herein.

This multi-channel amplifier includes the whole configuration of the multi-channel amplifier in the first embodiment, and further includes a Bus channel as the highest order channel, a changeover switches SW provided to the individual channels respectively, and a switching controlling portion Ctrl. for switching the changeover switch SW.

The Bus channel has a sound signal inputting portion BusIn with a pin jack, a buffer amplifier BusBuf, and a sound signal outputting portion BusOut.

In respective individual channels, a common contact of the changeover switch SW is connected to an input terminal of the amplifier circuit Amp. Out of two selection contacts of the changeover switch SW, a first selection contact is connected to the signal terminal S of the sound signal inputting portion In on the individual channel, and a second selection contact is connected to the signal terminal S of the sound signal inputting portion BusIn of the Bus channel.

The switching controlling portion Ctrl switches together the changeover switch SW-1L to 4L and SW-1R to 4R of all individual channels Ch-1(L/R) to Ch-4(L/R) collectively to the same side in response to an operation of the operator. When respective changeover switches SW are switched to the first selection contact side by the switching controlling portion Ctrl, the multi-channel amplifier operates in the similar way to the multi-channel amplifier in the first embodiment shown in FIG. 2. In contrast, when respective changeover switches SW are switched to the second selection contact side, the audio source being input into BusIn(L/R) is output from all channels.

In this manner, a mode in which the sound signal being input into BusIn is output from all individual channels in response to the switching is employed in the whole-building audio distributing system for home use in a situation of the home party, or the like. That is, this function is provided based on such a need that, when the whole building is opened and employed as one space for the home party, or the like, the same music should be furnished to all rooms. Therefore, such a mode is called a party mode that the changeover switches SW are switched collectively to the second selection contact side (BusIn side).

When the operation mode is not the party mode, it may be set individually every stereo channel whether the changeover switches SW on the first to fourth stereo channels should be switched to the second selection contact side (BusIn side) or the first selection contact (the sound signal inputting portion of each individual channel) side. In this case, switching patterns may be stored in advance in the switching controlling portion Ctrl, and then switching of respective changeover switches SW may be done based on the stored switching patterns when the operation mode gets out of the party mode. Alternately, the user may do the switching operation of the changeover switches SW every stereo channel by the manual operation.

### Third Embodiment

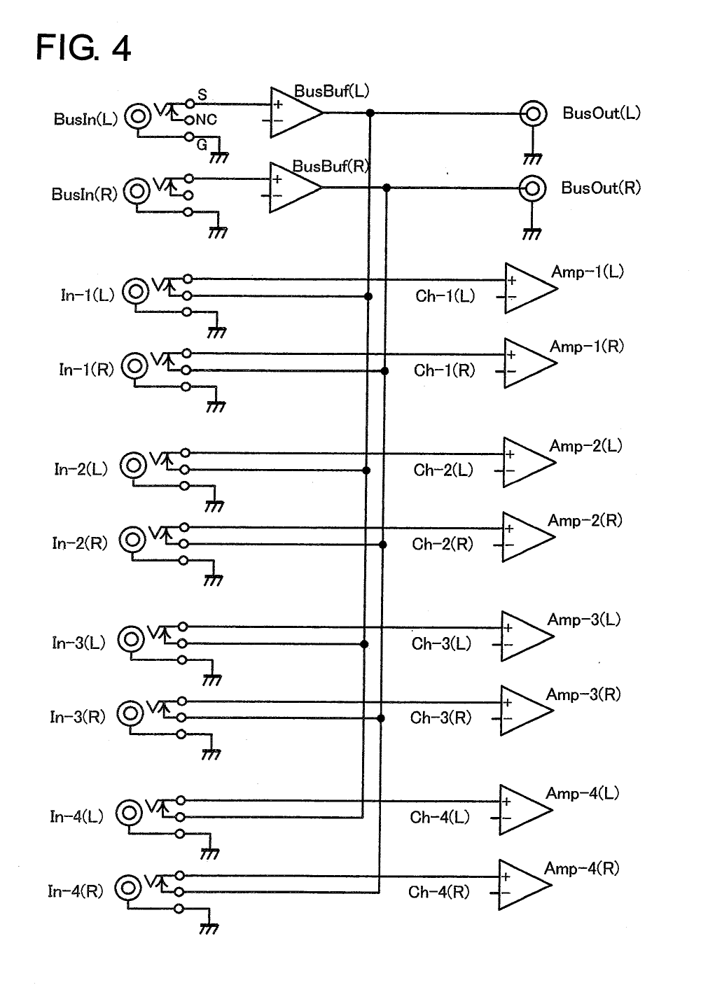

FIG. 4 is a block diagram of a multi-channel amplifier as a third embodiment of the present invention. This multi-channel amplifier has a pair of Bus channels and four pairs (eight) individual channels.

The Bus channel has the sound signal inputting portion BusIn with the pin jack, the buffer amplifier BusBuf, and the sound signal outputting portion BusOut.

Each individual channel has the sound signal inputting portion In having the pin jack with NC (Normally Close) contact, and the amplifier circuit Amp for amplifying the signal in the audio frequency band. Here, the pin jack with NC contact is the pin jack having the signal terminal S, the ground terminal G, and the NC contact. The NC contact means the contact that comes in touch with the signal terminal S when the plug is not inserted, but becomes separated from the signal terminal S when the plug is inserted. The signal terminal S of the pin jack is connected to the amplifier circuit Amp.

The signal terminal of the buffer amplifier BusBuf on the Bus channel is connected to the NC contact of the pin jack of each individual channel. That is, the signal on the Bus channel is input into the NC contact.

Accordingly, when the audio cable is connected (the pin plug is inserted) to the sound signal inputting portion (pin jack) In on each individual channel, the sound signal being input into the sound signal inputting portion In is input into the amplifier circuit Amp. In contrast, when the audio cable is not connected to the sound signal inputting portion In, the sound signal of the Bus channel being input via the NC contact is input into the amplifier circuit Amp.

Therefore, the input of the sound signal from the Bus channel is ON/OFF-controlled depending on whether or not the audio cable is connected (the pin plug is inserted). As a result, there is no need that the changeover switch should be provided to each individual channel and the switching operation of switching depending on whether or not the audio cable is connected should be done, and also the configuration can be simplified and an operating error can be eliminated.

### Fourth Embodiment

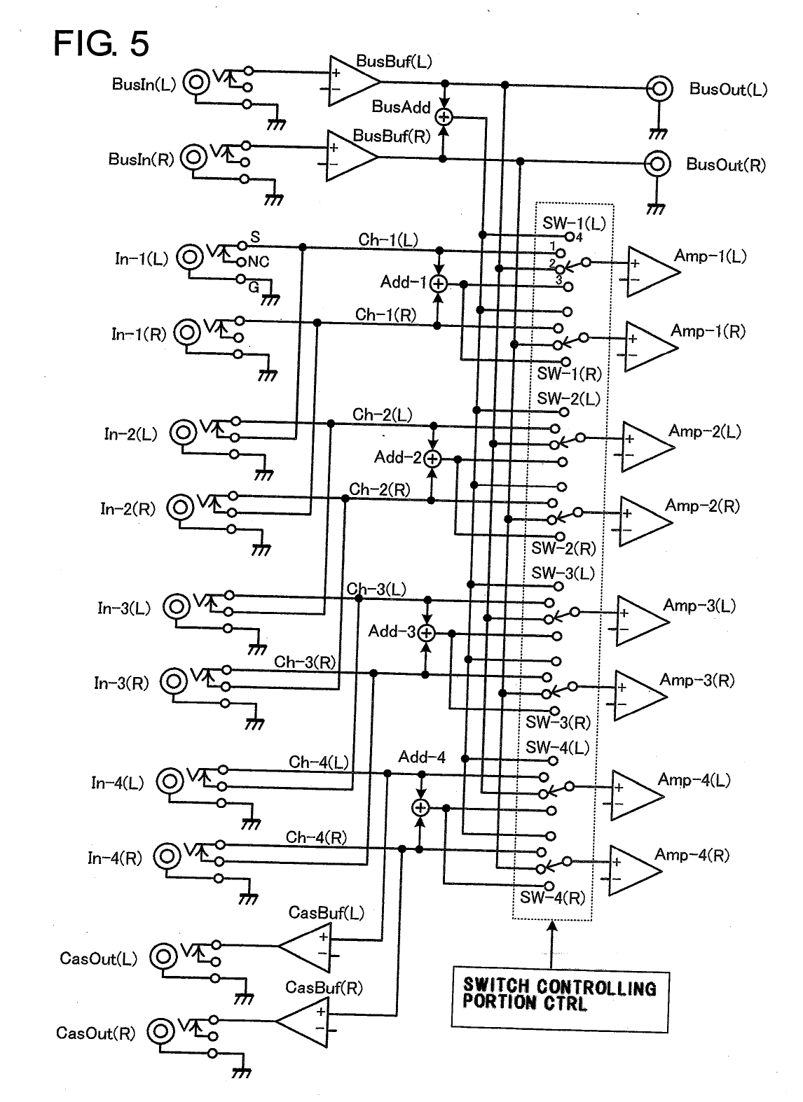

FIG. 5 is a block diagram of as a multi-channel amplifier of a fourth embodiment of the present invention. In this multi-channel amplifier, a monaural rechanneling circuit is added to the multi-channel amplifier in the second embodiment shown in FIG. 3. The “monaural rechanneling circuit” is a circuit that converts the L/R stereo signals in the monaural signal and reproduces the monaural signal from the L/R channels. Therefore, a changeover switch SW in this embodiment is constructed as a four-contacts changeover switch.

An adder for adding/synthesizing the input of the left channel and the input of the right channel is provided to the Bus channels for the L/R stereo inputs and the stereo channels respectively. A adder BusAdd on the Bus channel adds the sound signal being input from BusIn (L) and the sound signal being input from BusIn (R). An added output is fed to fourth selection contacts of the changeover switches SW on all individual channels. Also, an adder Add-n (n=1 to 4) is provided to the n-th stereo channel respectively. The adder Add-n adds the sound signal being input from In-n (L) and the sound signal being input from In-n (R). This added output is fed to third selection contacts of the left and right changeover switches on that stereo channel.

Accordingly, when the changeover switches SW-n(L/R) are switched to the third selection contact side on the n-th stereo channel, the sound signal obtained by converting the sound signal being input into this stereo channel into the monaural signal is input commonly to the amplifier circuits Amp-n(L/R). Also, when the changeover switch SW is switched to the fourth selection contact side on each stereo channel, the sound signal being input into the Bus channel and converted into the monaural signal is input into the amplifier circuit Amp on that stereo channel.

This monaural signal is chosen when people should hear the same sound in all locations. Such a situation may be switched collectively on all stereo channels that either the L/R stereo signals are output as they are or the monaural signal is output. Alternately, the above situation may be chosen/switched individually on each stereo channel.

In the same manner as the embodiment shown in FIG. 3, when the operation mode is not the party mode, such a situation may be set individually every stereo channel that either the changeover switches SW on the first to fourth stereo channels are switched to the second or fourth selection contact (BusIn) side or these changeover switches are switched to the first or third selection contact (the sound signal inputting portion on each individual channel) side. In this case, the switching patterns may be stored in advance in the switching controlling portion Ctrl., and then the switching of respective changeover switches SW may be done based on the stored switching patterns when the operation mode gets out of the party mode. Alternately, the user may do the switching operation of the changeover switches SW every stereo channel by the manual operation.

Here, the multi-channel amplifier of this embodiment is constructed as the two-channel (L/R) stereo configuration. But this multi-channel amplifier may be constructed as a monaural configuration. Further, this multi-channel amplifier may have a configuration oriented to the surround audio such as 5.1 channels, or the like, for example.

The multi-channel amplifier having the stereo configuration of the present embodiment may be set forth as the invention as follows.

(1) A multi-channel amplifier, includes

a plurality of channel arrays (L/R) in which a plurality of channels having a sound signal inputting portion and an amplifier circuit respectively are provided in parallel from an higher order to a lower order, and

a signal selecting portion provided between adjacent channels in each channel array respectively, for inputting a sound signal, which is to be input into an amplifier circuit on a higher order side, into an amplifier circuit on a lower order side when a sound signal is not input into a sound signal inputting portion on the lower order side from an outside.

(2) A multi-channel amplifier set forth in (1), further includes

a signal synthesizing portion for synthesizing the sound signals being input into the sound signal inputting portions (e.g., In-1(L), In-1(R)) on the corresponding channels of the plurality of channel arrays (L/R), and

a signal switching portion for inputting a synthesized signal commonly to amplifier circuits (e.g., Amp-1(L), Amp-1(R)) on the corresponding channels.

What is claimed is:

1. A multi-channel amplifier comprising:
first and second channels, each having an inputting connector to which an input plug is connectable and an amplifier circuit,
wherein the inputting connector of each of the first and second channel includes a signal terminal electrically connected to the amplifier circuit and a contact selectively and electrically connected to the signal terminal,
wherein the contact of the second channel is electrically connected to the signal terminal of the first channel,
wherein when the input plug is connected to the inputting connector of the second channel, the contact of the second channel is electrically separated from the signal terminal of the second channel and the input plug is electrically connected to the signal terminal of the second channel, and
wherein when the input plug is not connected to the inputting connector of the second channel, the contact of the second channel is electrically connected to the signal terminal of the second channel.

2. The multi-channel amplifier according to claim 1, wherein the contact is a NC contact.

3. The multi-channel amplifier according to claim 1, further comprising:
an external output terminal of the sound signal;
wherein the external output terminal is connected to the inputting connector of the second channel.

4. The multi-channel amplifier according to claim 3, further comprising:
a buffer circuit of a high input impedance provided between the inputting connector of the second channel and the external output terminal.

5. The multi-channel amplifier according to claim 1, further comprising:
a highest order channel having an outputting portion; and
signal selecting portions provided to the first and second channels, respectively, for selectively connecting one of the inputting connector of the corresponding first or second channel and the inputting connector of the highest order channel to the amplifier circuit of each channel.

6. The multi-channel amplifier according to claim 5, further comprising:
a switching controlling portion which switches the signal selecting portions on the first and second channels collectively to a same side.

7. A multi-channel amplifier comprising:
a first channel circuit having an inputting connector and an outputting portion; and
a plurality of second channels, each having an inputting connector to which an input plug is connectable and an amplifier circuit,
wherein the inputting connector of each of the second channels includes a signal terminal electrically connected to the amplifier circuit and a contact selectively and electrically connected to the signal terminal,
wherein the contact of each of the second channels is electrically connected to the outputting portion of the first channel,
wherein when the input plug is connected to the inputting connector of one of the second channels, the contact of the one of the second channels is electrically separated from the signal terminal of the one of the second channels and the input plug is electrically connected to the signal terminal of the one of the second channels, and
wherein when the input plug is not connected to the inputting connector of the one of the second channels, the contact of the one of the second channels is electrically connected to the signal terminal of the one of the second channels.

8. The multi-channel amplifier according to claim 7, wherein the contact is a NC contact.

9. A multi-channel amplifier comprising:
a first channel having an outputting portion;
a plurality of second channels, each having an inputting connector, an amplifier circuit and a signal selecting portion for selectively connecting one of the inputting connector of the first channel and the inputting connector thereof to the amplifier circuit thereof; and
a switching controlling portion which switches the signal selecting portions on the second channels collectively to a same side.
